(19) United States
(12) Patent Application Publication
(10) Pub. No.: US 2019/0270430 A1
(43) Pub. Date: Sep. 5, 2019

(54) ELECTRONIC KEY

(71) Applicant: DENSO CORPORATION, Kariya-city (JP)

(72) Inventor: Tetsuyuki ANZAI, Kariya-city (JP)

(21) Appl. No.: 16/419,402

(22) Filed: May 22, 2019

Related U.S. Application Data
(63) Continuation of application No. PCT/JP2017/040516, filed on Nov. 10, 2017.

(30) Foreign Application Priority Data
Dec. 9, 2016 (JP) 2016-239713

(51) Int. Cl. B60R 25/24; B60R 25/40; E05B 19/00; E05B 49/00; H05K 5/06; G07C 9/00; H04B 1/38

(52) U.S. Cl. CPC B60R 25/24; B60R 25/40; E05B 19/0082; E05B 2047/0048; H05K 5/06; G07C 9/00309; H04B 1/38; E05B 49/002

(57) ABSTRACT

An electronic key includes a mechanical key, a key housing to which the mechanical key is attached, and a charging terminal. The mechanical key is detachable from the key housing. The charging terminal is disposed in a key opposing surface that is a surface of the key housing, covered with the mechanical key in a state where the mechanical key is attached to the key housing, and exposed when the mechanical key is relatively moved from a position attached to the key housing.

### CROSS REFERENCE TO RELATED APPLICATIONS

The present application is a continuation application of International Patent Application No. PCT/JP2017/040516 filed on Nov. 10, 2017, which designated the United States and claims the benefit of priority from Japanese Patent Application No. 2016-239713 filed on Dec. 9, 2016. The entire disclosures of all of the above applications are incorporated herein by reference.

### TECHNICAL FIELD

The present disclosure relates to an electronic key, and more particularly to an electronic key provided with a mechanical key.

### BACKGROUND

There is known an electronic key that transmits and receives electronic information with wireless communication, instead of inserting a mechanical key into a key cylinder, to achieve a function similar to that in the case of inserting a mechanical key into a key cylinder.

### SUMMARY

The present disclosure describes an electronic key including a mechanical key, a key housing to which the mechanical key is detachably attached, and a charging terminal.

### BRIEF DESCRIPTION OF DRAWINGS

The above and other objects, features and advantages of the present disclosure will become more apparent from the following detailed description made with reference to the accompanying drawings, in which:

FIG. 1 is a perspective view illustrating an appearance of an electronic key of a first embodiment;

FIG. 2 is a perspective view of an electronic key in a state where a mechanical key is partially received in a key housing;

FIG. 3 is a sectional view taken along line III-III of FIG. 2;

FIG. 4 is an appearance perspective view of an electronic key of a second embodiment;

FIG. 5 is a sectional view taken along line V-V of FIG. 4;

FIG. 6 is an appearance perspective view of an electronic key of a third embodiment;

FIG. 7 is a sectional view taken along line VII-VII of FIG. 6;

FIG. 8 is a perspective view of a waterproofing cover and a terminal-port waterproofing sheet;

FIG. 9 is a plan view of an electronic key of a first modification;

FIG. 10 is a plan view of an electronic key of a second modification;

FIG. 11 is a view illustrating an electronic key in a state where a mechanical key is relatively moved from a position of FIG. 10; and

FIG. 12 is a perspective view of an electronic key of a third modification.

### DETAILED DESCRIPTION

An electronic key may be provided with a mechanical key in consideration of a case where electronic information cannot be transmitted and received such as a case where a built-in battery is dead. Greater functionality of an electronic key is studied, and a highly functional electronic key increases in power consumption. Thus, it is conceivable that a rechargeable battery is used as a built-in battery and an electronic key is provided with a charging terminal.

The charging terminal may be typically covered when not being in use. When an electronic key is provided with a charging terminal, a lid for covering the charging terminal may be further provided, resulting in an increase in the number of components.

According to an embodiment of the present disclosure, an electronic key may include a mechanical key, a key housing to which the mechanical key is attached, and a charging terminal. The mechanical key may be detachable from the key housing. The charging terminal may be disposed in a key opposing surface that is a surface of the key housing, and be covered with the mechanical key in a state where the mechanical key is attached to the key housing, while being exposed when the mechanical key is relatively moved from a position attached to the key housing.

In such a configuration, the key opposing surface is covered with the mechanical key in the state where the mechanical key is attached to the key housing. The charging terminal is disposed in the key opposing surface, so that the charging terminal is covered by the mechanical key in the state where the mechanical key is attached to the key housing. Thus, no dedicated component is required to be added to cover the charging terminal. As such, the electronic key is capable of covering the charging terminal while suppressing an increase in the number of components.

Hereinafter, embodiments of the present disclosure will be described with reference to the accompanying drawings.

### First Embodiment

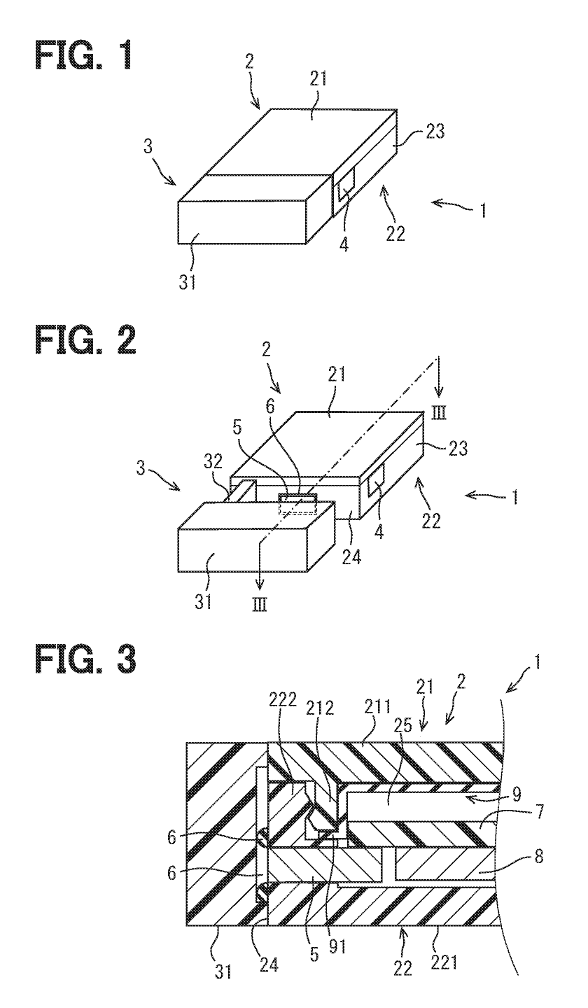

An electronic key 1 of a first embodiment illustrated in FIG. 1 includes a key housing 2 and a mechanical key 3. The electronic key 1 of the present embodiment is used for a vehicle. The electronic key 1 is used in a system that enables a user to lock and unlock a door, through communication between the electronic key 1 and an in-vehicle device, without touching the electronic key 1 as far as the user carries the electronic key 1.

The key housing 2 of the present embodiment has an external shape of a rectangular parallelepiped shape. However, the shape of the key housing 2 is not limited to the rectangular parallelepiped shape, and the key housing 2 may have various shapes such as a shape with a rounded corner and a shape with one entire end surface being curved. The key housing 2 is formed by combining an upper case 21 and a lower case 22. The upper case 21 and the lower case 22 are each made of a same resin. As the resin, a material called plastic is available.

In the present embodiment, two cases constituting the key housing 2 are referred to as the upper case 21 and the lower case 22 for convenience on the basis of the orientation of the electronic key 1 in FIG. 1. However, the electronic key 1 is naturally oriented in any directions when being carried. That is, the names of the upper case 21 and the lower case 22 do not indicate relative positions of the upper case 21 and the lower case 22 when being carried.

The mechanical key 3 has a grip portion 31 exposed from the key housing 2 in a state illustrated in FIG. 1. When the mechanical key 3 is housed in the key housing 2, namely, is attached to the key housing 2, or when the mechanical key 3 is removed from the key housing 2, and is used for operation of locking or unlocking, the grip portion 31 is held by a user.

The key housing 2 is provided with a release button 4 on its one lateral surface 23. Pressing the release button 4 causes the mechanical key 3 to be relatively movable from the key housing 2, so that the mechanical key 3 can be taken out from the key housing 2. That is, the mechanical key 3 is detachable from the key housing 2.

FIG. 2 illustrates a state where a rod-like portion 32 of the mechanical key 3 is partially inserted into the key housing 2. When the mechanical key 3 is relatively moved from its state of being housed in the key housing 2, namely, being attached to the key housing 2, a key opposing surface 24 being one surface of the key housing 2 is exposed as illustrated in FIG. 2. The key opposing surface 24 faces the grip portion 31 of the mechanical key 3 when the mechanical key 3 is housed in the key housing 2. In the present embodiment, the key opposing surface 24 is also in contact with the grip portion 31 through a waterproofing ring 6, which will be described hereinafter, interposed therebetween in the state where the mechanical key 3 is housed in the key housing 2. The rod-like portion 32 of the mechanical key 3 is inserted through the key opposing surface 24.

The rod-like portion 32 of the mechanical key 3 is invisible from the outside when the mechanical key 3 is housed in the key housing 2, as illustrated in FIG. 1. The rod-like portion 32 is inserted into the key cylinder for use of the mechanical key 3, and corresponds to an insertion portion. The grip portion 31 of the mechanical key 3 is exposed from the key cylinder when the rod-like portion 32 is inserted into the key cylinder, so that a user can hold the grip portion 31.

A charging terminal 5 is provided in the key opposing surface 24 of the key housing 2. That is, an opening of the charging terminal 5 is exposed in the key opposing surface 24, and the opening of the charging terminal 5 is almost coplanar with the key opposing surface 24. The charging terminal 5 is a terminal into which a charge cable for supplying electric power to a battery 8 (refer to FIG. 3) disposed inside the key housing 2 is inserted. At a portion of the key opposing surface 24, around the opening of the charging terminal 5, a waterproofing ring 6 is fixed. The waterproofing ring 6 is made of an elastic resin. The waterproofing ring 6 corresponds to a terminal-port waterproofing member. As the elastic resin, silicon rubber is available, for example. In the present description, the silicon means silicon resin that may be also referred to as silicone. The waterproofing ring 6 can be molded together with the lower case 22 by composite molding (two-color molding, insert molding, etc.), for example.

FIG. 3 illustrates a sectional view taken along line III-III of FIG. 2. As illustrated in FIG. 3, the upper case 21 includes a body part 211 having a plate shape, and an engagement protrusion 212 protruding perpendicularly from the body part 211. The lower case 22 includes a body part 221 having a plate shape, and a sidewall part 222 erecting perpendicularly from an edge of the body part 221 to form the lateral surface 23, the key opposing surface 24, and the like of the key housing 2.

The engagement protrusion 212 of the upper case 21 is engaged at its leading end with a portion of the sidewall part 222, facing the engagement protrusion 212, to form the key housing 2 defining a housing space 25 therein.

The housing space 25 houses a circuit board 7, the battery 8, a waterproofing cover 9 and the like, in addition to the charging terminal 5. The circuit board 7 is provided with a wireless circuit element for performing the wireless communication with the in-vehicle device. The battery 8 supplies electric power to the wireless circuit element mounted on the circuit board 7. The battery 8 is a secondary battery that is charged with electric power supplied through the charge cable connected to the charging terminal 5.

The waterproofing cover 9 is made of silicon rubber. The waterproofing cover 9 is attached to and is closely in contact with an inner surface of the upper case 21. The waterproofing cover 9 is configured to have an end that closes a clearance between the lower case 22 and the upper case 21. FIG. 3 illustrates an edge portion 91 of the waterproofing cover 9, being sandwiched and compressed between a tip end of the upper case 21 and the lower case 22.

As illustrated in FIG. 3, the waterproofing ring 6 is pressed by the grip portion 31 in the state where the mechanical key 3 is attached to the key housing 2. In the state illustrated in FIG. 3, the grip portion 31 is in close contact with the waterproofing ring 6. When the grip portion 31 is brought into close contact with the waterproofing ring 6, the waterproofing ring 6 is compressed to suppress ingress of water into the charging terminal 5.

In the first embodiment described hereinabove, the charging terminal 5 is disposed in the key opposing surface 24, and the key opposing surface 24 is covered with the grip portion 31 in the state where the mechanical key 3 is attached to the key housing 2. Thus, no dedicated component is required to be added to cover the charging terminal 5. The electronic key 1 of the present embodiment is capable of covering the charging terminal 5 while suppressing an increase in the number of components.

The charging terminal 5 is invisible from the outside when the mechanical key 3 is attached to the key housing 2. Thus, design of the electronic key 1 improves.

In addition, the charging terminal 5 is opened and closed by holding and moving the grip portion 31 of the mechanical key 3. Thus, the charging terminal 5 can be easily opened and closed, as compared with a configuration in which the charging terminal 5 is covered with by a rubber cover or the like.

In the present embodiment, the waterproofing ring 6 surrounding the opening of the charging terminal 5 is disposed around the opening of the charging terminal 5 in the key opposing surface 24. The waterproofing ring 6 is in close contact with the grip portion 31 of the mechanical key 3 and is compressed in the state where the mechanical key 3 is attached to the key housing 2. This enables suppressing ingress of water into the charging terminal 5.

### Second Embodiment

Next, a second embodiment will be described. In descriptions of the second embodiment and the subsequent embodiments, elements with reference signs having the same numerals as those of the reference signs having been already used are identical to the elements with the same reference signs in the prior embodiment, unless otherwise specified. When only a part of structure is described, the earlier described embodiment can be applied to the other parts of the structure.

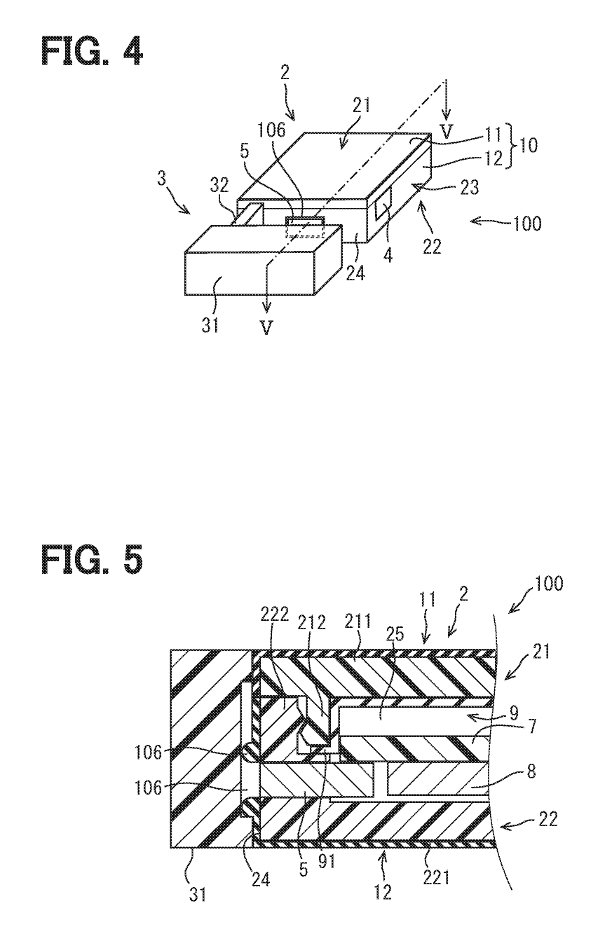

FIG. 4 is an appearance perspective view of an electronic key 100 of the second embodiment. The electronic key 100 has a shape similar to that of the electronic key 1 of the first embodiment. The electronic key 100 of the second embodiment is different from the electronic key 1 of the first embodiment in that the electronic key 100 includes an outer cover 10 made of silicon rubber on an outer surface of the key housing 2. The outer surface means a surface exposed to the outside.

The key housing 2 is made of the upper case 21 and the lower case 22, so that the outer cover 10 also includes an upper cover 11 covering an outer surface of the upper case 21, and a lower cover 12 covering an outer surface of the lower case 22. The upper cover 11 and the lower cover 12 are each made of silicon rubber in the present embodiment.

The electronic key 100 of the second embodiment includes a waterproofing ring 106 made of silicon rubber at the same position as that of the waterproofing ring 6 of the first embodiment. FIG. 5 illustrates a sectional view taken along line V-V of FIG. 4. As illustrated in FIG. 5, the waterproofing ring 106 forms an integrally molded part together with the lower cover 12 that is made of silicon rubber as with that of the waterproofing ring 106.

Thus, in the second embodiment, the waterproofing ring 106 can be molded together with the lower case 12 by composite molding (two-color molding, insert molding, etc.) at a time, so that the number of manufacturing processes can be reduced.

### Third Embodiment

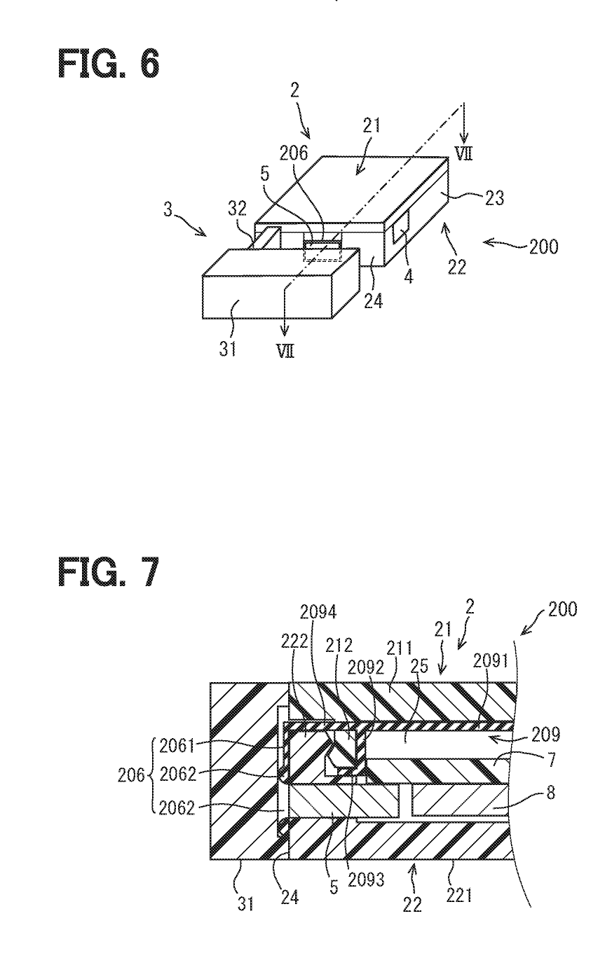

FIG. 6 is an appearance perspective view of an electronic key 200 of a third embodiment. As illustrated in FIG. 6, the electronic key 200 of the third embodiment is configured such that a terminal-port waterproofing sheet 206 in contact with the key opposing surface 24 is exposed in a state where the grip portion 31 of the mechanical key 3 is separated from the key opposing surface 24. The terminal-port waterproofing sheet 206 corresponds to a terminal-port waterproofing part.

As illustrated in FIG. 7, the terminal-port waterproofing sheet 206 forms an integrally molded part together with a waterproofing cover 209 attached to an inner surface of the upper case 21. The waterproofing cover 209 and the terminal-port waterproofing sheet 206 are each made of silicon rubber.

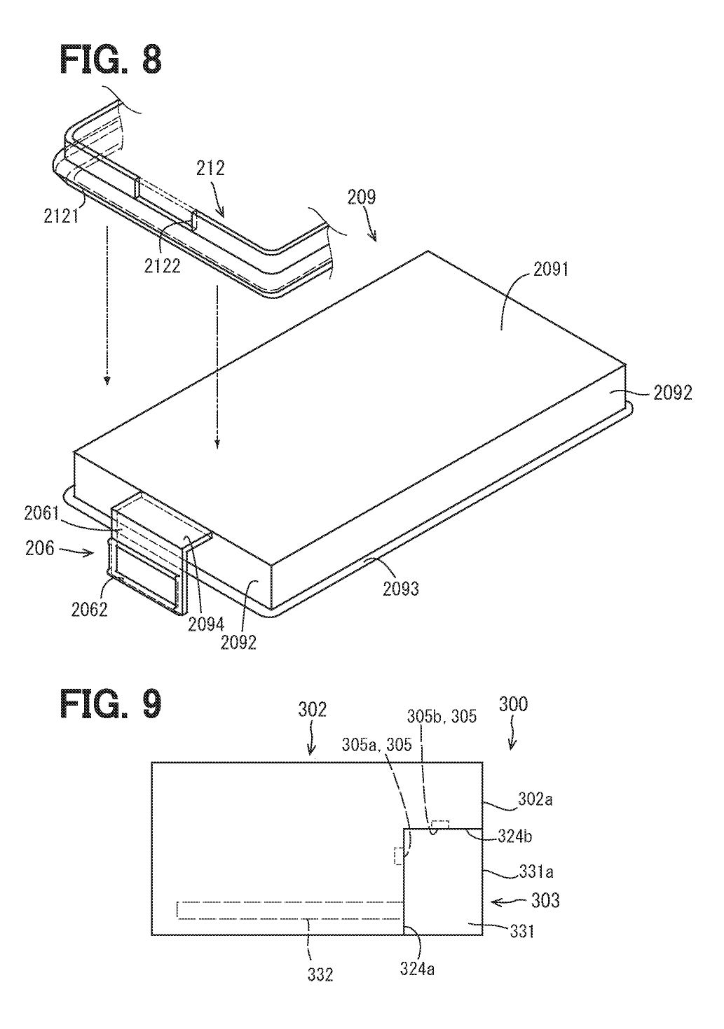

As illustrated in FIG. 8, the waterproofing cover 209 includes a cover body portion 2091, an erected portion 2092, a projecting portion 2093, and an extended portion 2094. The cover body portion 2091 is in contact with the inner surface of the upper case 21. The cover body portion 2091 of the present embodiment thus has a rectangular sheet shape in accordance with the inner surface of the upper case 21.

The erected portion 2092 erects almost perpendicularly from a peripheral edge of the cover body portion 2091. The projecting portion 2093 projects from a leading end of the erected portion 2092 toward an outer periphery of the upper case 21. The extended portion 2094 is extended parallel to the cover body portion 2091 from a side of the cover body portion 2091 provided with the key opposing surface 24, in the state where the waterproofing cover 209 is attached to the upper case 21, and the upper case 21 and the lower case 22 are engaged with each other. The extended portion 2094 is coupled at its end opposite to the cover body portion 2091 with a coupling portion 2061 of the terminal-port waterproofing sheet 206. The extended portion 2094 has a lateral length, namely, a length in a direction orthogonal to a direction in which the extended portion 2094 projects from cover body portion 2091 in a plane including the extended portion 2094, being equal to a lateral length of the coupling portion 2061 of the terminal-port waterproofing sheet 206.

The terminal-port waterproofing sheet 206 includes the coupling portion 2061 and a ring portion 2062. The coupling portion 2061 couples the ring portion 2062 with the extended portion 2094 of the waterproofing cover 209. The ring portion 2062 has the same shape as that of the waterproofing ring 6 of the first embodiment.

FIG. 8 also illustrates the engagement protrusion 212 of the upper case 21. The body part 211 of the upper case 21 is eliminated in FIG. 8 to illustrate a relationship between the engagement protrusion 212 and the waterproofing cover 209.

The engagement protrusion 212 has a lower surface 2121 that has a rectangular-loop shape corresponding to the projecting portion 2093 of the waterproofing cover 209. The lower surface 2121 of the engagement protrusion 212 is in contact with the projecting portion 2093 of the waterproofing cover 209 in the state where the waterproofing cover 209 is attached to the upper case 21.

When the waterproofing cover 209 is attached to the upper case 21, the engagement protrusion 212 is moved relative to the waterproofing cover 209, as shown by arrows in FIG. 8. The erected portion 2092 of the waterproofing cover 209 is brought into contact with an inner surface of the protrusion 212, and the extended portion 2094 and the terminal-port waterproofing sheet 206 are led to the outside of the protrusion 212 through a window 2122.

As illustrated in FIG. 7, a part of the erected portion 2092 is brought into contact with an inner surface of the engagement protrusion 212. In addition, a part of the projecting portion 2093 is interposed between the engagement protrusion 212 and the sidewall part 222 of the lower case 22, and is held by the engagement protrusion 212 and the sidewall part 222 of the lower case 22.

The terminal-port waterproofing sheet 206 is in contact with the key opposing surface 24, and the ring portion 2062 of the terminal port waterproofing sheet 206 surrounds the opening of the charging terminal 5.

In the third embodiment, the terminal-port waterproofing sheet 206 forms an integrally molded part together with the waterproofing cover 209. Thus, the terminal port waterproofing sheet 206 and the waterproofing cover 209 can be molded at a time, so that the number of manufacturing processes can be reduced.

While the embodiments of the present disclosure are described hereinabove, the present disclosure is not limited to the embodiments described hereinabove. The following modifications are included in the technical scope of the present disclosure, and various changes other than the following may be made without departing from the gist of the present disclosure.

<First Modification>

FIG. 9 illustrates an electronic key 300 of a first modification. The electronic key 300 of the first modification is configured such that a grip portion 331 of a mechanical key 303 does not project from a key housing 302. The key housing 302 of the first modification is configured such that a top surface 331a of the grip portion 331 is almost coplanar with a narrow end surface 302a of the key housing 302.

The key housing 302 includes two key opposing surfaces 324a and 324b, and a rod-like portion 332 of the mechanical key 303 is inserted into the key housing 302 through the key opposing surface 324a parallel to the narrow end surface 302a. The rod-like portion 332 corresponds to an insertion portion.

A charging terminal 305a is provided in the key opposing surface 324a, and a charging terminal 305b is provided in the key opposing surface 324b. In the first modification, two charging terminals 305, such as the charging terminal 305a and the charging terminal 305b, are disclosed to show that the charging terminals 305a and 305b can be disposed in the two key opposing surfaces 324a and 324b, respectively. Any one of the two charging terminals 305 may be provided as a matter of course.

<Second Modification>

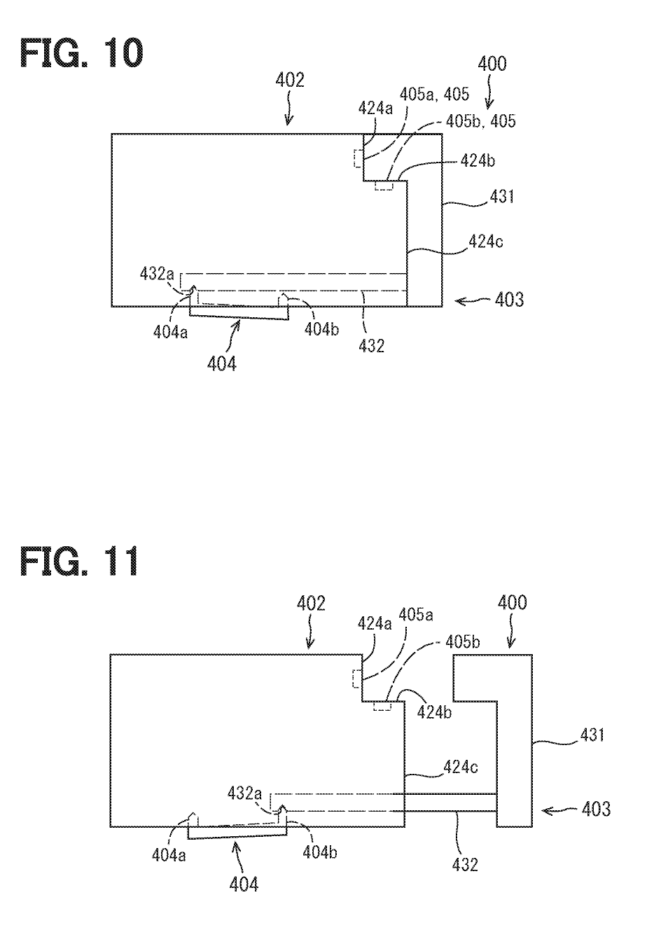

FIG. 10 illustrates an electronic key 400 of a second modification. A key housing 402 includes three key opposing surfaces 424a, 424b, 424c. The mechanical key 403 includes a grip portion 431 and a rod-like portion 432, and the rod-like portion 432 is inserted into the key housing 402 through the key opposing surface 424c. The rod-like portion 432 corresponds to an insertion portion.

Charging terminals 405a and 405b are provided in the key opposing surfaces 424a and 424b, respectively. Also in the second modification, two charging terminals 405, such as the charging terminal 405a and the charging terminal 405b, are disclosed to show that the charging terminals 405a and 405b can be disposed in the two key opposing surfaces 424a and 424b, respectively. Any one of the two charging terminals 405 may be provided as a matter of course.

In particular, the key opposing surface 424b is parallel to a direction in which the mechanical key 403 is moved with respect to the key housing 402, and does not face the rod-like portion 432 of the mechanical key 403 when the mechanical key 403 is inserted into or removed from the key housing 402. As illustrated in FIG. 11, the charging terminal 405b is provided in the key opposing surface 424b such that a charge cable can be easily inserted into the charging terminal 405b even in a state where the rod-like portion 432 of the mechanical key 403 is not completely removed from the key housing 402.

In a case where the charge cable is inserted into the charging terminal 405b with the rod-like portion 432 that is not completely removed from the key housing 402, it is preferable that the rod-like portion 432 be fixed to the key housing 402 even when the rod-like portion 432 is partially received in the key housing 402. In such a case, possibility of loss of the mechanical key 403 at the time of charging can be suppressed.

The electronic key 400 includes a release button 404 of a seesaw type to fix the rod-like portion 432 to the key housing 402 in the state where the rod-like portion 432 is partially received the key housing 402.

The release button 404 includes two protrusions 404a and 404b at positions different from each other in the longitudinal direction of the rod-like portion 432 in the state where the mechanical key 403 is received in the key housing 402. The release button 404 enables a state where the protrusion 404a relatively enters the inside of the key housing 402, and a state where the protrusion 404b relatively enters the inside of the key housing 402.

In the state illustrated in FIG. 10, the protrusion 404a is engaged with a recessed portion 432a formed in a leading end of the rod-like portion 432. Meanwhile, in the state illustrated in FIG. 11, the protrusion 404b is engaged with the recessed portion 432a. As such, the electronic key 400 is capable of fixing the mechanical key 403 at the two positions including the position illustrated in FIG. 10 and the position illustrated in FIG. 11.

The release button 404 of a seesaw type is an example of a structure in which the mechanical key 403 is fixed at the respective two positions illustrated in FIGS. 10 and 11. Another structure may allow the mechanical key 403 to be fixed at two positions including an attached position illustrated in FIG. 10 and an intermediate position illustrated in FIG. 11.

<Third Modification>

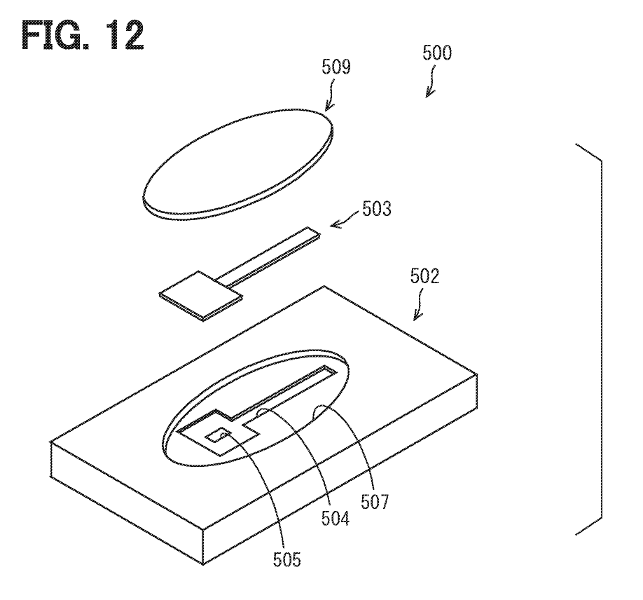

FIG. 12 illustrates an electronic key 500 of a third modification. The electronic key 500 is configured such that a mechanical key 503 is received in a key recessed portion 504 formed in a key housing 502 to be attached to the key housing 502. Thus, the key recessed portion 504 corresponds to a key opposing surface. A charging terminal 505 is provided in the key recessed portion 504. Accordingly, when the mechanical key 503 is received in the key recessed portion 504, the charging terminal 505 is covered with the mechanical key 503.

The electronic key 500 further includes a lid 509, and a lid recessed portion 507 is formed in the key housing 502. In normal time, the lid 509 is received in the lid recessed portion 507. The key recessed portion 504 is formed in a part of the lid recessed portion 507.

<Fourth Modification>

Also in the first, second, and third modifications, the waterproofing ring 6 may be provided around each of the charging terminal 305a, 305b, 405a, 405b, and 505.

<Fifth Modification>

In place of the silicon rubber, there may be available another elastic resin such as a kind of resin, called an elastomer. The elastic resin may be a resin with rubber elasticity.

<Sixth Modification>

The electronic keys 1, 100, 200, 300, 400, and 500 each may be used as a key other than that for a vehicle.

<Seventh Modification>

In the embodiments described hereinabove, the upper case 21 and the lower case 22 are joined by engaging to each other in each of the embodiments. Alternatively, the upper case 21 and the lower case 22 may be joined by using an adhesive, a double-sided tape, ultrasound welding, laser welding, or the like.

What is claimed is:

1. An electronic key comprising:
a mechanical key;
a key housing to which the mechanical key is attached; and
a charging terminal, wherein
the mechanical key is detachable from the key housing, and
the charging terminal is disposed in a key opposing surface that is a surface of the key housing, covered with the mechanical key in a state where the mechanical key is attached to the key housing, and exposed when the mechanical key is relatively moved from a position attached to the key housing,
the electronic key further comprising:
a terminal-port waterproofing part made of an elastic resin, the terminal-port waterproofing part being positioned on the key opposing surface to surround a periphery of the charging terminal, and being in contact with the mechanical key in the state where the mechanical key is attached to the key housing to suppress ingress of water into the charging terminal; and
an outer cover made of an elastic resin and covering an outer surface of the key housing, wherein
the terminal-port waterproofing part and the outer cover are provided by an integrally molded part.

2. An electronic key comprising:
a mechanical key;
a key housing to which the mechanical key is attached; and
a charging terminal, wherein
the mechanical key is detachable from the key housing, and
the charging terminal is disposed in a key opposing surface that is a surface of the key housing, covered with the mechanical key in a state where the mechanical key is attached to the key housing, and exposed when the mechanical key is relatively moved from a position attached to the key housing,
the electronic key further comprising:
a terminal-port waterproofing part made of an elastic resin, the terminal-port waterproofing part being positioned on the key opposing surface to surround a periphery of the charging terminal, and being in contact with the mechanical key in the state where the mechanical key is attached to the key housing to suppress ingress of water into the charging terminal; and
a waterproofing cover made of an elastic resin and attached to an inner surface of the key housing, wherein
the terminal-port waterproofing part and the waterproofing cover are provided by an integrally molded part.

3. The electronic key according to claim 1, wherein
the mechanical key includes an insertion portion that is to be inserted into a key cylinder, and a grip portion that is exposed from the key cylinder to allow a user to hold the grip portion when the mechanical key is inserted into the key cylinder, and
the charging terminal is disposed in the key opposing surface, at a position facing the grip portion in the state where the mechanical key is attached to the key housing.
